(19) United States
(12) Patent Application Publication
(10) Pub. No.: US 2003/0135998 A1
(43) Pub. Date: Jul. 24, 2003

(54) Method, facility and device for producing an electrical connecting element, electrical connecting element and semi-finished product

(76) Inventors: Silke Walz, Sarnen (CH); Phillipe Steiert, Greppen (CH); Walter Schmidt, Russikon (CH)

Correspondence Address: RANKIN, HILL, PORTER & CLARK, LLP, 700 HUNTINGTON BUILDING, 925 EUCLID AVENUE, SUITE 700, CLEVELAND, OH, 44115-1405, US

(21) Appl. No.: 10/169,570

(22) PCT Filed: Jan. 4, 2001
(86) PCT No.: PCT/CH01/00004

(30) Foreign Application Priority Data
Jan. 4, 2000 (DE) 100 00 090.8

(51) Int. Cl. B05D 5/12; H05K 3/02

(52) U.S. Cl. 29/854; 29/846; 427/97; 29/832; 29/830

(57) ABSTRACT

The method for producing an electrical connecting element is essentially characterized in that a plastic deformable substrate is formed with an embossing tool in an embossing step in such a way that recesses are made in said substrate in the areas in which conductive strips and, for instance, through holes or contact surfaces should be formed. The substrate is then coated with a thin conductive layer. In a following step, conductive material is galvanically deposited on the substrate until the recesses are filled with conductive material. Subsequently, the conductive material is removed the corresponding areas of the substrate that should not have any conductive surface are free from any metal coating.

The invention relates to the field of manufacture of electrical connecting elements, for example circuit boards, high-density-interconnects, ball grid array (BGA) substrates, chip scale packages (CSP), multi-chip-module (MCM) substrates, etc. It especially relates to a method, to a connecting element, to a semi-finished product as well as to an installation and to a device, according to the independent claims.

The constantly advancing miniaturisation in the field of microelectronics also has its effect on the manufacture of electrical connecting elements, in particular circuit boards, interconnects, etc. In many fields of application there exists the necessity of replacing the conventional manufacture of circuit boards with new methods step by step. The conventional manufacture of conductor structures is based on the photo-chemical method and the mechanical drilling of passage holes. Newer set-ups include the drilling of the smallest of holes by way of lasers or by way of plama etching or by way of the mechanical pressing of perforation tools into circuit board material (microperforation, cf. the international patent publication WO 00/13062 to this).

Whilst the drilling of micro-holes is increasingly carried out with new methods meeting the up-to-date demands, the structuring of conductive tracks as always is carried out with the tried and trusted methods of photo-structuring. This however involves a multitude of manufacturing steps, including exposure, developing, and the stripping of photoresist. It is thus relatively complicated and also has disadvantages from the environmental point of view.

In the US patent document U.S. Pat. No. 6,035,527 there is suggested a set-up with which one proposes making use of a modem hole forming technique also for manufacturing strip conductors. The set-up is based on the fact that one manufactures recesses of an essentially rectangular cross section in the substrate by way of laser ablation. Subsequently the complete substrate is provided with a thin conductive layer, for example by way of a chemical vapour deposition (CVD) method. After this, in a selective method this layer is removed everywhere where no strip conductors (conductor paths) are to arise, i.e. everywhere except for in the recesses. This selective removal may for example likewise be accomplished by way of laser ablation. Subsequently metal is chemically deposited, wherein the regions of the conductive layer which have not been removed serve as a seed layer. The number of wet-chemical processes is reduced by way of this method. However several sequential laser ablation steps are carried out, which is why the method is too slow for complex circuit boards. According to one variant at least the second laser ablation step is eliminated. This is effected in that after depositing the thin, conductive layer in a manner known among the experts for a long time, the whole substrate is coated with metal galvanically or by way of chemical deposition until a level surface arises. The layer which arises by way of this is subsequently etched away until only material in the strip conductors is present. This method has the following disadvantages: The sequentially functioning laser removal, which with chemical methods carried out conventionally lead to large layer thicknesses having to be etched away and the unfavourable reachable ratio between the depth and width (aspect ratio) of the strip conductors. Furthermore it has been shown that when etching away the metal layer, practically one may not avoid etching out the very shallow recesses, by way of which interruptions arise. The manufacture of deep channels by way of laser ablation is however not suitable alone for reasons of economics. Furthermore this method does not permit narrow, deep channels on account of the previously indicated unfavourable, achievable aspect ratios.

In contrast to the conventional method, in the US patent document U.S. Pat. No. 6,005,198 there is described a method for manufacturing circuit boards, which amongst other things envisages the simultaneous impressing of U-shaped grooves and of cup-shaped recesses by an embossing tool into an insulating and preferably duroplastic substrate. For forming pocket holes out of the cup-shaped recesses for the electrical connecting between two conductor layers, material must subsequently further be chemically or mechanically removed away. Thereupon the grooves and the recesses are metallised. This is effected for example in that a conductive paste is pressed into the recesses with a rubber roller. Alternatively to this one may also coat the whole substrate and subsequently introduce insulating material (etchresist) into the recesses with a rubber roller. In an etching process following this the metal layer present in the recesses is protected on account of the etchresist. By way of this method one saves a few processing steps. The method however requires several wet-chemical processes as was previously the case. On account of the relatively wide U-shape of the recesses necessary for this method to function, the miniaturisation furthermore has its limits. Moreover the strip conductors due to design either consist of a relatively poor-conductive, curable paste (“conductive ink”) or they are comparatively thin. For this reason limits are also set to the reliability which may be achieved and to the power which may be transmitted by the strip conductors. The method has not been shown to be so successful in practice since the impressing of the conductor pastes or of the etchresist always entails the smearing of these materials on the remaining surface. The surface however must be absolutely free and clean, which leads to the fact that this must be mechanically ground after the coating process and the curing.

It is the object of the invention to provide a new method for the manufacture of circuit boards. In order to meet the even higher demands in comparison to the state of the art with regard to the efficiency of the method, the costs and the miniaturisation, the following points should be fullfilled:

all method steps must run as parallel as possible. Sequential method steps make the manufacture more complex and expensive.

the number of wet-chemical steps must be kept as low as possible for reasons of economics of the method and for ecological reasons.

the required number of method steps as a whole should be reduced in comparison to existing methods.

the method should allow the structures such as strip conductors and passage holes to have lateral dimensions which are as small as possible. At the same time however the reliability and the conductive ability should not be reduced in comparison to the state of the art. With strip conductors there therefore results the demand that they should have cross sections which are less flat in comparison to existing systems, i.e. should have a sufficiently large cross section.

finally on account of the increasingly finer and more complex structures which may be achieved, one should avoid having to position the product relative to a tool with an accuracy which takes into account the fineness of the structures.

The invention provides for a method with these characteristics and is defined in the patent claims.

The method is essentially distinguished in that in an embossing step an elastically deformable substrate is deformed with an embossing tool in a manner such that there arise recesses where strip conductors and for example also passage holes or contacting surfaces are to arise. Subsequently there is effected a coating of the substrate with a thin conductor layer. In a next step the whole substrate is galvanically covered with conductor material until the recesses are filled up with conductor material. After this, by way of a removal process, conductor material is removed until those locations of the substrate which are not to have a conductive surface are free of a metal coating.

At the same time preferably at least a few structures have a cross sectional area in which the aspect ratio (the ratio of depth to width) is at least 1:2, for example at least 1:1 and preferably is between 1:2 and 5:1.

According to a preferred embodiment form a plasma aftertreatment is effected after the embossing step. By way of this, the passage holes for example at the locations provided for this may be freed from residual layers.

The circuit board manufacture according to the invention is amazingly simple. One requires a single deformation step, a coating step and two wet-chemical steps. The coating step as well as both wet-chemical methods steps are carried out over the whole surface on the substrate as a whole and therefore—as with e.g. the laser ablation method, do not require a lateral positioning of the substrate with respect to a tool. They may therefore be carried out very simply. The embossing step too—after setting up the embossing tool—requires no form of accuracy on handling, even for the manufacture of the finest of structures. Additionally the optimisation of the strip conductor cross sections may be solved in an extremely simple manner with the invention. The strip conductors may for example have an essentially rectangular cross section which however at the same time has a considerably more favourable aspect ratio compared to the state of the art.

The invention is based on a series of new and surprising findings.

A first finding is the fact that there exist thermoplasts and also duroplasts which in an excellent manner are suitable for embossing circuit board substrates. Examples of such substrates are liquid crystal polymers, (LCPs). Further possibilities are polysulfones, epoxy resins which are deformable via the second order transition temperature, certain polyesters (PEEK), polycarbonates etc.

A further finding is the fact that embossing tools may be manufactuured with almost any structure. This finding is already partly described in the international published patent application WO 00/13062 whose contents are included here.

Additionally there also exists the very surprising finding that the galvanic filling of essentially channel-shaped, e.g. long-drawn recesses which have an aspect ratio of more than 1:2 and for example 1:1 or larger is possible. The ratio between the structure depth and as a whole when galvanising may also be surprisingly favourable. The galvanising is also possible without so-called “bubble cavities” from occuring, i.e. incomplete filling of the recesses. These resulted automatically with conventional galvanic methods according to the state of the art, since in these on account of the electrical field distribution the material which is galvanised on preferably collects at the surface and at the edges and not in the recesses. If one fills the recesses galvanically according to the state of the art, inasmuch as this was at all possible, the so-called “reverse-pulse-plating” method was applied. According to this method the current is commutated several times which leads to the fact that material is alternately deposited on the substrate and removed again. With this in the optimal case a “bubble cavity” formation may be avoided, but the expense with regard to apparatus, the energy which must be applied and the increased manufacturing time are however great disadvantages.

In the following, embodiment examples of the invention are yet described in more detail by way of the drawings. In the drawings:

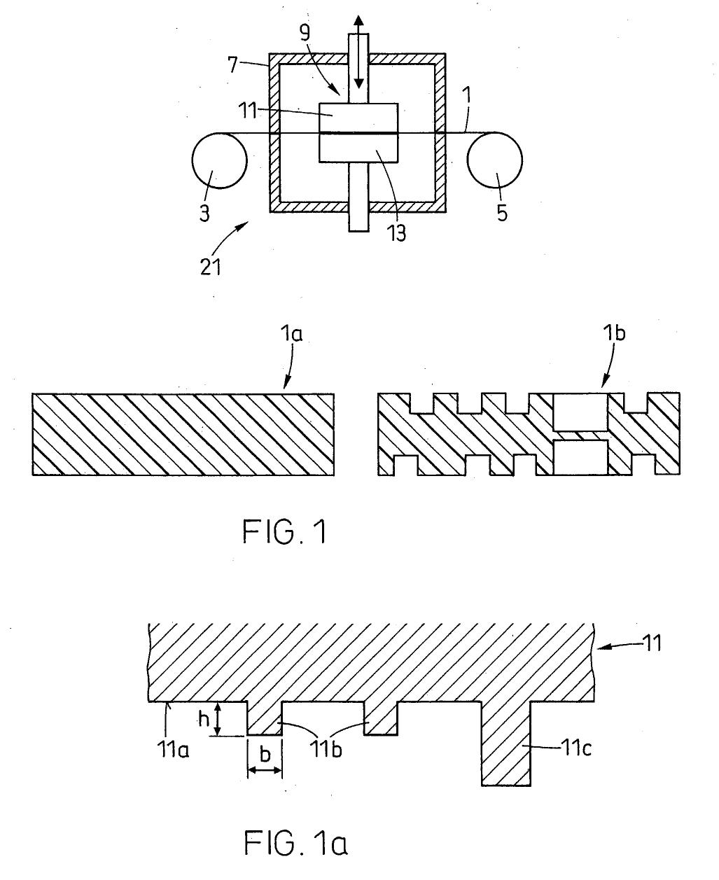

FIGS. 1 and 5 show the sequence of method steps of one embodiment form of the method according to the invention by way of very shematic drawings of corresponding devices,

FIG. 1a schematically shows a section through a section of an embossing die,

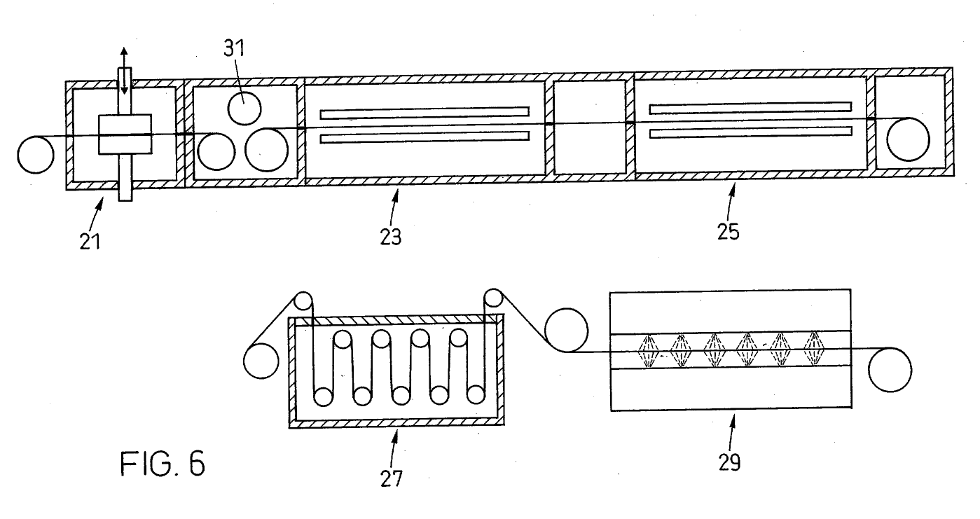

FIG. 6 schematically shows an example of an installation for the manufacture of circuit boards with the method according to the invention,

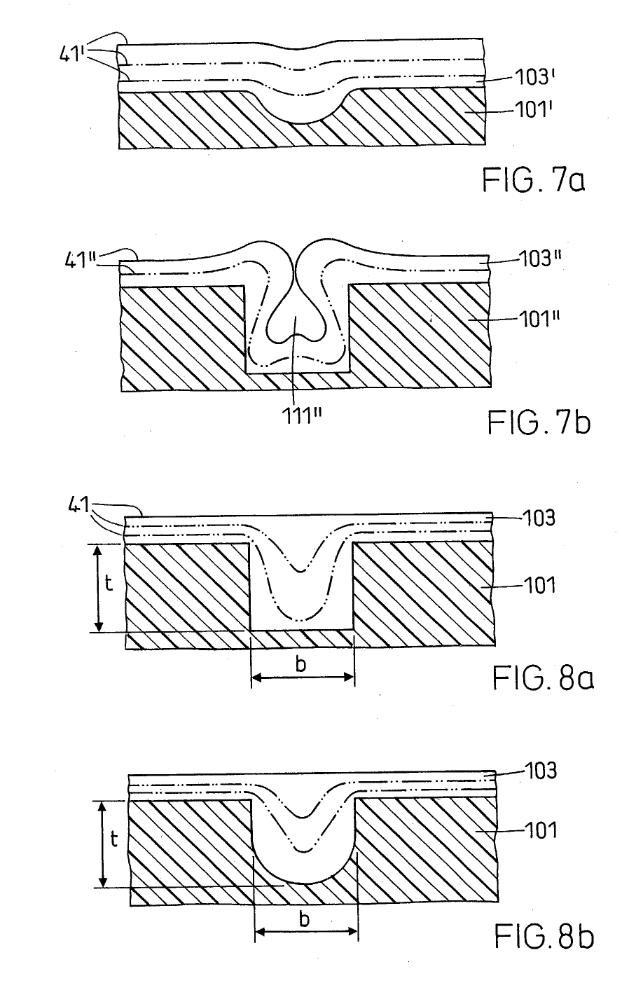

FIGS. 7a and 7b show examples of galvanisation procedures according to the state of the art,

FIGS. 8a and 8b show examples of strip conductors filled galvanically according to the invention, in a cross section perpendicular to the surface of the substrate,

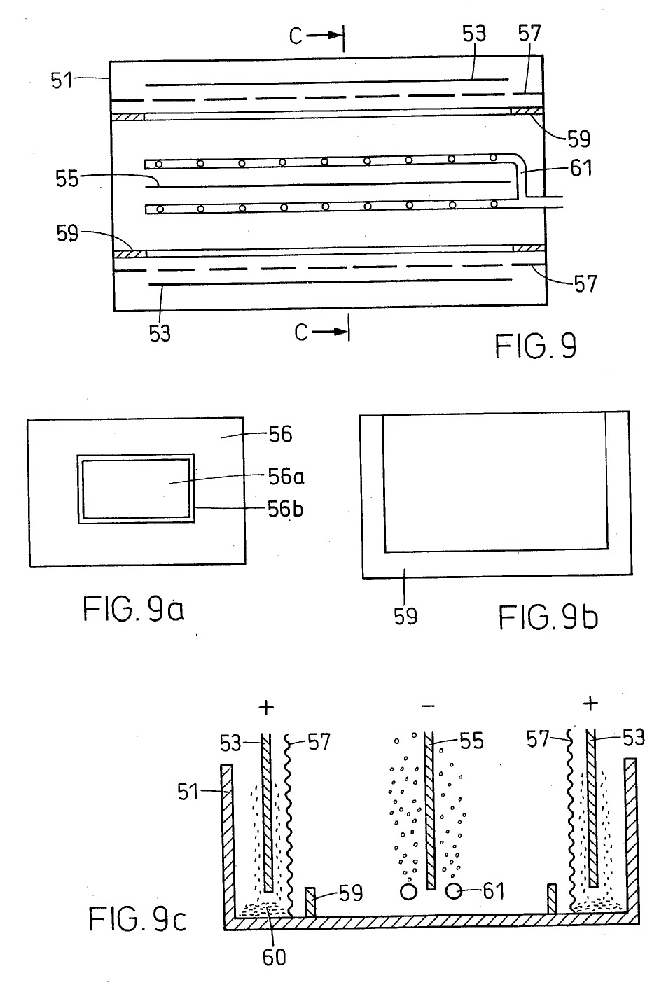

FIG. 9 schematically shows a plan view of a container sectioned along a horizontal plane, for carrying out the galvanic process step as a batch process,

FIGS. 9a and 9b show details of FIG. 9,

FIG. 9c shows a vertical section through the arrangement of FIG. 9,

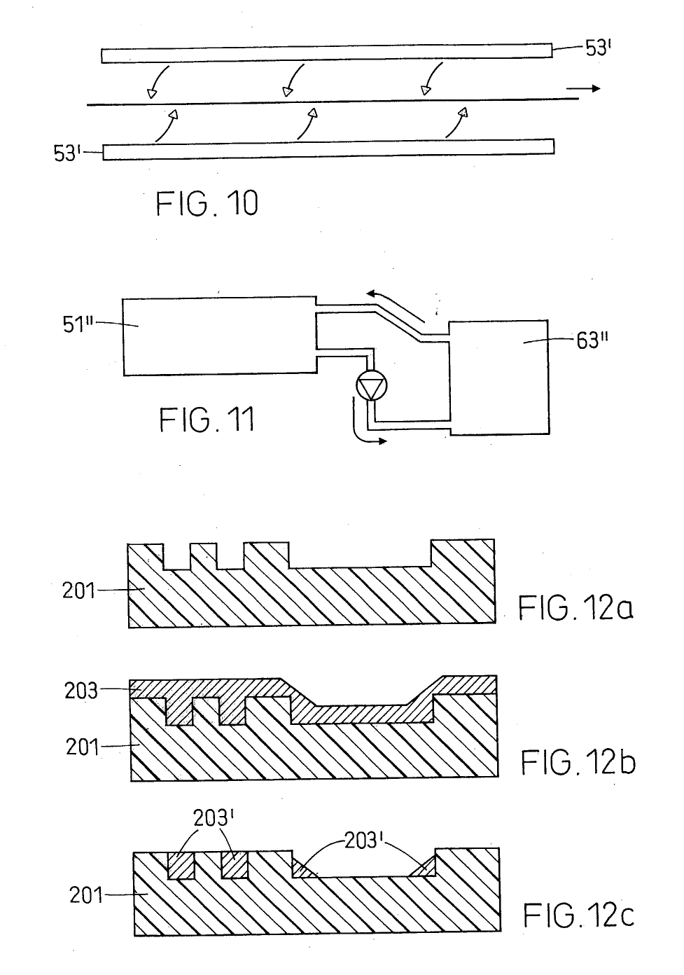

FIG. 10 shows very schematically an example of an arrangement for carrying out the galvanic process step as a continous process,

FIG. 11 shows a scheme for the electrolyte circulation according to a special variant,

FIGS. 12a, 12b and 12c show sections through a region of a circuit board during various stages in the manufacturing process,

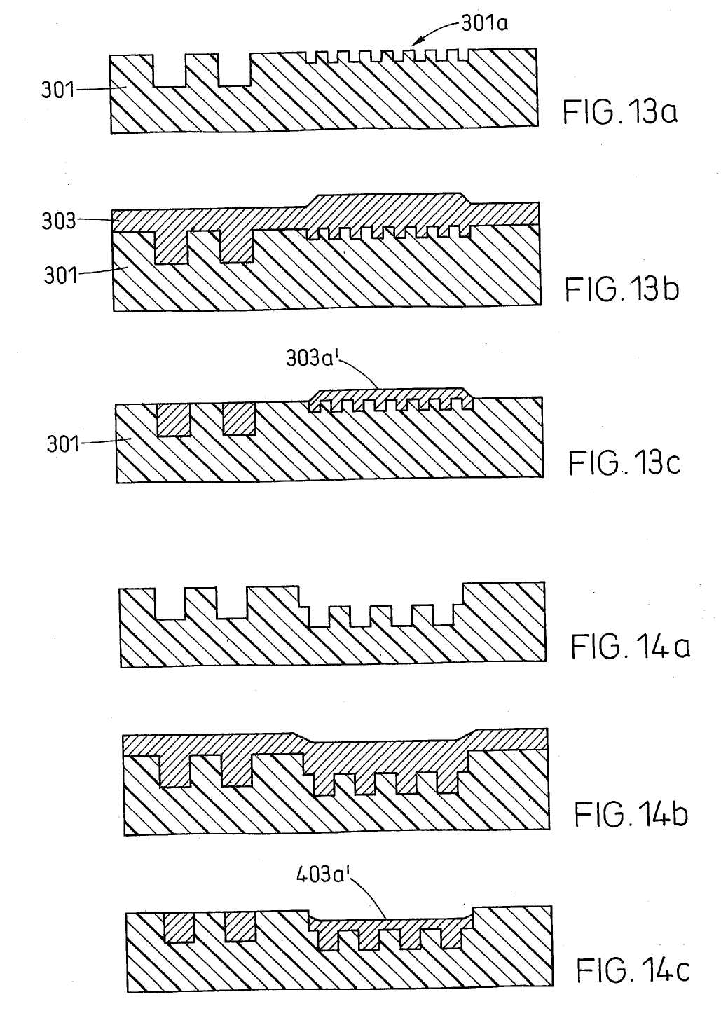

FIGS. 13a, 13b and 13c show sections through a region of one embodiment form of the electrical connecting element according to the invention during various stages of manufacture,

FIGS. 14a, 14b and 14c show sections through a region of a further embodiment form of the electrical connecting element according to the invention during various stages of manufacture.

In FIG. 1 there is shown schematically a substrate 1a. This in the example shown here is a liquid crystal polymer (LCP) foil. The substrate is also drawn for forming a multitude of substrates for electrical connecting elements, specifically for an endless foil 1 envisaged for circuit boards.

Liquid crystal polymers are polymeric plastics in which the individual molecules are “frozen” in a partially arranged alignment to one another. Liquid crystal polymers are known per se. They are thermoplastics with a series of properties which in an excellent manner are suitable for use as a circuit board substrate. They are thus for example dimensionally stable, self-quenching and absorb hardly any water. The value of the relative permittivity εᵣ is roughly 2.9 which is very advantageous for high-frequency circuits.

The method according to the invention may of course also be carried out with substrates other than LCP foils. In particular substrates which are thicker than foils according to their usual definition are conceivable. Also plastically deformable materials other than LCPs are possible, wherein here the specialised literature is referred to.

A device 21 for embossing electrical connecting elements is shown in FIG. 1. It comprises a dispensing roll 3 and a receiving roll 5 which are both arranged outside an embossing chamber 7. An embossing tool 9, for example a micro-embossing tool comprising and upper 11 and a lower embossing die 13 projects into inside of the embossing chamber. The substrate foil 1 is guided by the dispensing roll 3, the receiving roll 5 and by openings in walls of the embossing chamber such that it extends through the embossing chamber 7. Alternatively the dispensing and the receiving roll may also be arranged in the inside of the embossing chamber. An embossing step envisages the mutual pressing of both embossing dies 11, 13. With this recesses are simultaneously incorporated onto the substrate on both sides. At least some of these recesses are essentially channel-shaped. The substrate foil is wound onto the receiving roll 5 subsequent to the embossing. For the embossing step the substrate is heated to a temperature according to the substrate material, at which it is plastically deformable. The processed substrate 1b which arises on account of the embossing step is likewise shown in the figure.

In FIG. 1a there is further shown a detail of the upper embossing die 11. The embossing stamp is for example manufactured with the LIGA method and has a surface 11a and projections 11b, 11c projecting beyond this. With this one may differentiate between ridge-shaped or ridge-like projections 11b which are extended in one direction (in the drawing parallel to the plane of the picture) and form channel-like recesses for strip conductors and pin-like projections 11c for forming passage holes. At least some of the ridge-like projections 11b have a cross section 11a perpendicular to the surface, in which the width b at the most is double the size of the height h. In the example shown here the embossing stamp is metallic, it may however be manufactured of any other material which is harder for example than copper.

In the example described here there are drawn two embossing dies between which the substrate is pressed with the embossing step. It is however also conceivable for only one embossing die to be present, which is pressed against the substrate which rests on a hard surface. In this case the substrate is of course only provided with recesses on one side.

It is also possible for the embossing step to comprise several different embossing procedures. Thus for example one may effect a coarse embossing step produced with a coarse embossing tool and subsequently a fine embossing step with a fine embossing tool.

The embossing step, alternatively to mutually pressing two embossing dies, may be accomplished also via rotating rollers (“roller embossing”).

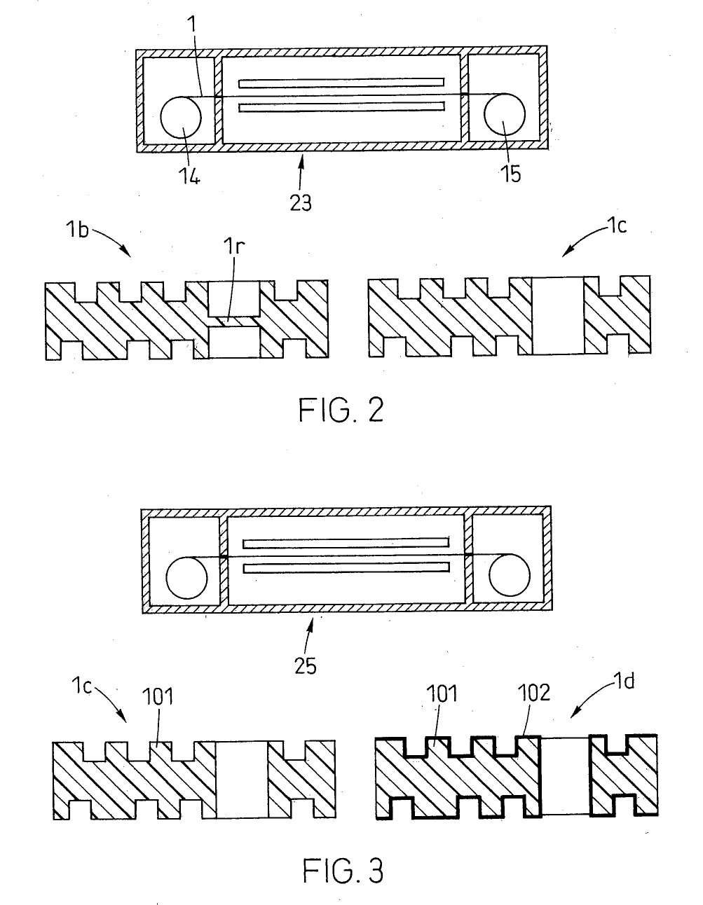

The aftercleaning or aftertreatment step shown in FIG. 2 is effected for example by plasma etching. Alternatively to this a wet-chemical process would also be conceivable. The plasma etching step is effected in a plasma etching device 23 in a manner which is known per se and is described several times in publication. With this the substrate 1 is for example tensioned between a dispensing roll 13 and a receiving roll 15. The aftertreatment step fullfills the purpose of removing material remnants 1r still remaining and not removed by the embossing tool. Such material remnants 1r for example remain on the embossed substrate 1b at locations where passage holes are to arise. The aftertreated substrate 1c is likewise schematically shown in FIG. 2.

In a further step according to FIG. 3 a coating with a thin conductor layer is deposited. This may be effected for example in a vacuum chamber by way of sputtering. Other methods such as chemical vapour deposition (CVD), thermal vapour-deposition, anodic vapour-deposition or further chemical or physical methods are conceivable. Copper is preferably used as a coating material, but other conductor materials such as silver etc. are also possible. With certain polymer materials copper may be directly deposited without there occuring problems with adhesive strength. In other cases firstly so-called adhesive layers of chromium, titanium or wolfram may be deposited. In a second layer usually copper is deposited. In such a case the thin conductor layer is composed of two or possibly more metallic layers.

The coating step too is effected for example in a device 25 with a dispensing and receiving roll, between which rolls the substrate foil is tensioned. The coating layer has the job of making the substrate conductive for the subsequent galvanic treatment and forming an interface between the insulating substrate material and the conductive material which has been galvanised on. The coating device 25 in FIG. 3 is like the aftercleaning device of FIG. 2 and is shown only very schematically. The man skilled in the art without further ado would recognise which elements a coating device must have (for example means for producing and maintaining a vacuum, for example an ion source, at least one target and where necessary ion deflection means when the coating device is sputter device). The substrate before the coating step 1c and—after the coating step—is also shown in FIG. 3 as a substrate layer (dielectric) 101 with a coating 102.

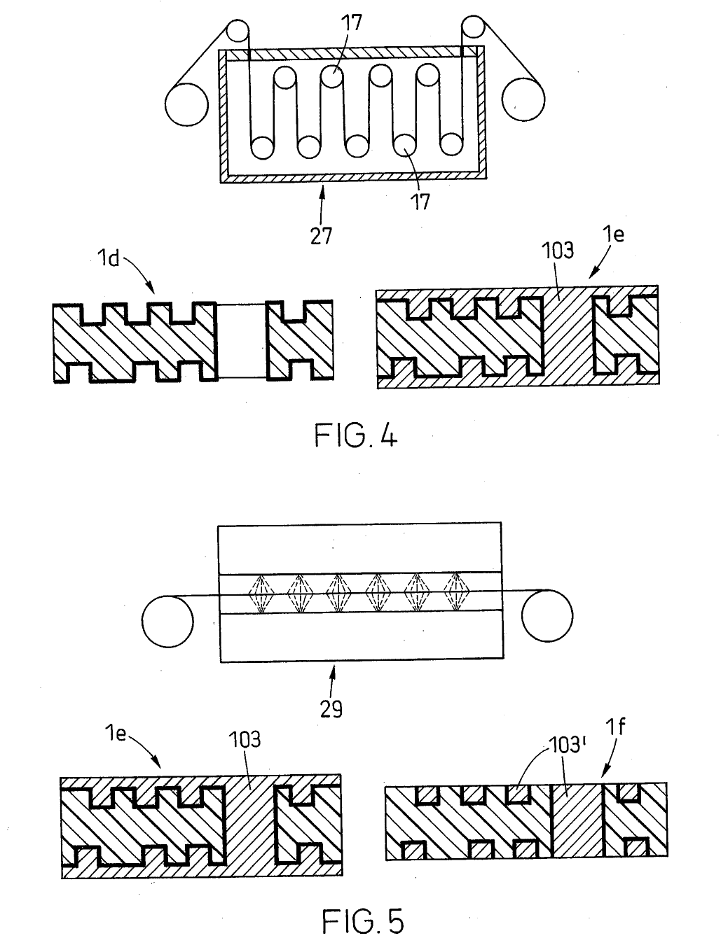

After the coating has been effected, conductor material is deposited on the whole substrate, until the recesses are filled out, as is shown in FIG. 4. This is effected galvanically in an electrolyte cell. At the same time for the plating process for example one does not apply a reverse pulse plating, i.e. with the galvanising process the polarity is not reversed or for example reversed twice at the most. Copper, but basically also other conductor materials are considered, for example silver. The device 27 for this processing step for example also comprises rolls 17 between which the intermediate product is tensioned. The arrangement shown here is very schematic, the electroplating step will be dealt with in more detail later. The product before the processing step is indicated at 1d, and after the processing step is indicated at 1e. After the processing step the substrate layer comprises a plating 103 filling the recesses and furthermore also extensively covering the whole substrate.

Therefore in a further step according to FIG. 5 the plating is removed for so long until the conductor material 103′ is only still present at the locations at which it is envisaged, thus in the recesses for strip conductors, passage holes and at contact locations. The removal is for example effected wet-chemically by etching. The etching back is effected in an etching-back device 29 in a manner known per se, for example in a chemical bath or, as shown, by spraying with an etching solution. Alternatively to etching one may also apply other removal methods, for example mechanical removal methods (for example fine grinding—“lapping”) or further chemical or physical removal methods.

For all previously mentioned working steps, methods for holding the substrate other than the “reel-to-reel” method of tensioning the substrate formed as a foil between two rolls shown in the figures are also conceivable. Alternatives for example are a suspension or holding a shape-rigid substrate only at the edge, the tensioning or adhesion of the substrate onto a plate, the tensioning of the substrate into a frame, etc.

The method steps described above are preferably carried out in an installation for the automised manufacture of circuit boards. As is shown schematically in FIG. 6 such an installation consists of a vacuum section and a section for carrying out the wet-chemical processes. The vacuum section comprises devices for carrying out the embossing step 21, for aftercleaning by way of plasma ablation 23 and for coating 25. The vacuum section furthermore comprises several chambers. The section for carrying out the wet-chemical steps comprises an electroplating device 27 and an etching device 29. Essential features of the individual devices were already explained by way of the description of the method steps. The devices are therefore not described again here.

Alternatively to the arrangement of FIG. 6, the embossing device may also be attached outside the vacuum, and the embossing is thus carried out in an oxygen-containing atmosphere or for example under a protective gas.

For example, in contrast to the device already described by way of FIG. 1 and also shown in FIG. 6, the device for carrying out the embossing step 21 may also have several embossing dies. In this case a parallel embossing takes place on several substrates. Furthermore between the individual devices there may yet also be present storage rolls 31 (“buffer rolls”) in addition to the dispensing and receiving rolls. These for example serve as a storage and buffer and are in particular to be provided between devices with different cycle times.

In the following, the step of galvanising-on the conductor material is dealt with. Until now only flat structures have been considered for the galvanic filling with conductor material. Amongst other things the reason for this is that when galvanising, the material by nature settles where the electrical fields are large, thus preferably at corners and edges. The embodiment example of the invention which is to be described here is however based on the fact that strip conductors which have a cross section with which the aspect ratio as the ration of depth to width is at least 1:2 and for example approximately 1:1 or more are preformed and filled.

In FIGS. 7a and 7b it is indicated how one galvanises according to the state of the art. In these figures as with the following figures for reasons of clarity the hatching for the galvanised-on metal layers has been omitted. In FIG. 7a there is shown a typical substrate form 101′ which has a thin coating and onto which a conductor layer 103′ was galvanised. The shown lines 41′ show the course of the surface with various quantities of deposited material. Since the conductor material 103″ when galvanising onto the coated substrate 101′ preferably settles at corners and hardly at all in the recesses, a type of cavity “bubble cavity” 111′ is formed when the ratio between the width and the depth of the recess to be filled becomes small. For this reason recesses with which the aspect ratio is more than 1:3, 1:2 or even 2:3 or 1:1 were not considered for galvanic filling. The invention also permits this region to be accessible.

In the FIGS. 8a and 8b there are shown recesses which are filled according to the embodiment example of the invention. The lines 41 at the same time represent the surface of the conductor layer 103 during various stages of the galvanising. As can be clearly deduced from the figure, a flat surface is achieved very quickly. The dashed line in the figures represents the surface plane of the substrate. The dimensions b and t stand for the width and depth of the recess respectively. Apart from the approximately rectangular or U-shaped cross sections shown in the figures, any other cross sections of the recesses which may be created with an embossing die are conceivable.

The galvanising or electroplating with copper according to the embodiment example described here may be carried out in a device according to the FIGS. 9 and 9c. Here there is described a batch process where a sample is incorporated into an electrolyte cell, processed and subsequently removed from the cell. FIG. 9 schematises the plan view of a device for galvanising in a vertical arrangement. FIG. 9c shows a section along the line C-C of FIG. 9. The device comprises a container 51 in which peripherally there are attached two anode rods 53 and centrally a cathode rod 55. The cathode rod serves for holding and containing a steel plate 56 with an opening, which is shown in FIG. 9a in a front view and in a reduced scale. The opening 56a is provided with a gripping device 56b which serves for holding the coated substrate. Furthermore there are further provided a diaphragm 57 and an aperture 59. The diaphragm 57 serves for preventing any anode slime 60 from getting into the electrolyte surrounding the cathode. The aperture serves as the laterally limited shielding from currents or from electrical fields (see FIG. 9b). Furthermore there are provided means 61 which are formed as perforated dielectric tubes and through which there is effected the air-injection which is required for each acid copper electrolyte. Additionally there are yet present pump and filter means which are not illustrated, by way of which the electrolyte is led away, filtered and led again to the container. The electrolyte circulation effected by these means is for example 3 to 5 times the electrolyte volume per hour.

In the galvanic method step, the composition of the electrolyte is essential for recesses which also have a relatively large aspect ratio as previously mentioned to be able to be filled without “bubble cavities”.

Surprisingly it has been found out that methods of conventional galvanising technology for decorative purposes—with suitable adaptations—may be used for this purpose. Such methods until now were not considered for application in circuit board technology (or for the use for electrical connecting elements generally). Until now they have been used exclusively for providing surfaces with a gloss (decoration). They have until now not been used for depositing material on surfaces with recesses, in general of structured surfaces or very generally for functional galvanising technology.

According to a first embodiment form the electrolyte has the following components:

sulphuric acid (H₂SO₄): 10-200 g/L

copper sulphate (CuSO₄x5H₂O): 50-500 g/L

sodium chloride (NaCl): 10-250 mg/L, as well as the organic additions

HSO C-WL base gloss of the company HSO in Solingen, Germany: 0.5-5 mL/L

HSO C-WL gloss substrate: 0.5-5 mL/L

HSO C-WL gloss addition: 0.05-2 mL/L

The results with the following parameters are particularly advantageous:

Sulphuric acid 45-70 g/L, copper sulphate 200-230 g/L, sodium chloride 100-190 mg/L, HSO CWl basic gloss 2.2-4.2 mL/L, HSO C-WL gloss substrate 1.6-2.8 mL/L, HSO C-WI gloss addition 0.15-0.9 mL/L.

Optimal results are achieved with 45-60 g/L sulphuric acid, 210-230 g/L copper sulphate, 140-170 mg/L sodium chloride, 2.6-3.8 mL/L HSO C-WI basic gloss, 1.7-2.5 mL/L HSO C-WL gloss substrate and 0.2-0.6 mL/L, HSO C-WL gloss addition.

According to a second embodiment form, for the anorganic components the same compositions are used as for the first embodiment form:

sulphuric acid (H₂SO₄): 10-200 g/L, preferably 45-70 g/L and for example 45-60 g/L copper sulphate (CuSO₄x5H₂O): 50-500 g/L, preferably 200-230 g/L and for exampe 210-230 g/L sodium chloride (NaCl): 10-250 mg/L, preferably 100-190 mg/L and for example 140-170 mg/L. The organic components are however made available in the (conventional galvanic technological) HSO C-OF method of the company Schmidt in Solingen (DE).

In FIG. 10 there is further shown a device for carrying out the embodiment example of the method according to the invention as a continuous process. A horizontal arrangement is shown very schematically. However, in particular in large installations, more complicated arrangements with deflection rollers are conceivable. In this embodiment form as a continous process one requires no mounting for the coated substrate. The substrate 1 (with coating) functioning as a cathode is designed as a bendable foil as previously described and is tensioned by rollers. It is for example moved during the whole process and is pulled through the electrolyte container in the horizontal direction. The anodes 53′ are attached above or below the substrate or on both sides of the substrate. The device comprises air inflow means and where appropriate also diaphragms and apertures which are not to be described here once again. Additionally there are nozzles which are not shown and which are provided for the continous flow of electrolyte. By way of this flow, symbolised in the figures by arrows, the electrolyte is prevented from being depleted locally in the vicinity of the cathode in the course of time.

A schematic diagram of a variant for carrying out the method according to the invention is shown in FIG. 11. In this variant the copper precipitation process on the coated substrate is effected in an electrolysis cell 51″ which is separated from a container 63″ in which copper is brought from a solid condition into the electrolyte in solution. At the same time a continous circulation of electrolyte is effected, wherein depleted electrolyte is transported from the electrolysis cell 51″ into the container 63″ and electrolyte enriched with copper is transported from the container into the electrolysis scell.

The method according to the invention is particularly suitable for manufacturing fine structures with large aspect ratios >1:2 since the depth of the channels are also limited by the thickness of the dielectric used. Since the thickness lies in the region of 10-200 micrometers, the conductor channels usually have widths between 10 and maximum 100 micrometres. In applications for circuit boards one may specially manufacture the finest conductive tracks in a very simple and economical manner. In practically all applications however larger surfaces furnished with metal are necessary. Thus for example the contact surfaces for the components to be soldered onto the circuit board are mostly relatively large and the current supply leads (Vcc and GND) must often be designed with a large surface. After galvanising, these surfaces would have a copper layer thickness which is too small and after thinning-away the copper the copper would be etched away in these large-area regions. FIGS. 12a, 12b and 12c illustrate this schematically. With this FIG. 12a shows a substrate 210 after the embossing step. In FIG. 12b the same substrate is shown, wherein after the coating and electroplating step it is provided with a copper layer 203. After etching-back, according to FIG. 12c copper remains only in the vicinity of the steps as well as in the recesses.

In order to be able to manufacture these large-surfaced structures with the method according to the invention, one may select various design measures:

The surface to be designed as a contact surface is screened into fine structures. This may for example be accomplished by fine channels which either running parallel or cross and which have an aspect ratio which is optimal for the method according to the invention. In such a case current supply plane or also screen plane may be manufactured since these too are mostly designed screened-on in conventional applications. If however connecting surfaces are to be manufactured for soldering, then the screened surface would not permit a good soldering quality and the method must be modified so that closed soldering surfaces are formed.

One possibility is shown in the FIGS. 13a, 13b and 13c where in a manner anologous to the FIGS. 12a to 12c there is shown an electrical connecting element after the embossing step, after the electroplating step or after the etching. The possibility lies in screening the large-surface regions with very fine structures 301a given to the substrate 310 during the embossing step. These structures comprise recesses and projections lying between these. The depth of these structures, i.e. of the recesses for example lies below T/2, where T represents the depth of the channel-shaped recesses for strip conductors. This leads to an artificial thickening of the copper in these fine screen zones and a closed residual layer 303a′ remains after thinning away the copper. The screening may be effected in many ways, e.g. parallel conductive tracks, crossing conductive tracks, etc.

This effect may also be achieved in that one manufactures an embossing tool which apart from the fine structures with recesses and projections lying between these also contains larger, large-surface structures. A suitable electrical connecting element is shown in FIGS. 14a, 14b and 14c during various stages of manufacture. On galvanising, the fine structures are filled up quickly and finally the sheet-like structures are galvanised on. Summed this results in a slightly thicker copper layer in these large-surface regions and after thinning away the copper there remains a closed residual layer 403a′, i.e. the projections are still covered with copper after the etching-back step.

The screening of the large-surface regions for soldering surfaces also has the advantage that the copper layer is mechanically rigidly anchored on the dielectric, by which means the adhesive strength of the soldering surfaces is greatly increased.

The embodiment examples by way of which the invention has been previously described are limited to the manufacture of circuit boards. With the knowledge of the invention the man skilled in the art would recognise without further ado that the invention is just as suitable for the manufacture of other electrical connecting elements.

Furthermore with the above description, for the sake of simplicity, it was assumed that the product of the method is a finished connecting element. The man skilled in the art would of course recognise without further ado that additionally to the previously described steps one may undertake further processing steps for manufacturing an electrical connecting element. Such a semi-finished product may for example be processed for example with other components into a multilayer electrical connecting element.

Electrical connecting elements which may be manufactured with the method according to the invention may have a multitude of possible embossings and may be generally applied in fields in which electrical connecting elements are applied. Apart from conventional applications with which the circuit board is equipped with elements electrically coupled to one another a connecting element according to the invention is of course perfectly suitable for applications in which the miniaturisation is far advanced. Moreover, applications in which the current loadability of the strip conductors is important are also referred to. Such applications are favoured in that as previously described, a connecting element according to the invention may have tracks with an especially favourable cross section. Thus it is shown for example that connecting elements according to the invention may function as planar coils, wherein with a suitable flexible formation of the material by folding the coils on one another, one may form multilayer planar coils.

1. A method for manufacturing an electrical connecting element, characterised by the following method steps:
a. preparing a substrate (101, 201, 301, 401) of a plastically deformable polymeric material,
b. mechanical deformation of the substrate by way of an embossing tool (9) so that there arise essentially channel-shaped recesses where strip conductors are to arise,
c. coating the substrate with a first electrically conductive layer (102),
d. galvanising the substrate, which galvanising fills the recesses, until an essentially level surface of a second electrically conductive layer has arisen on the substrate,
e. removing away deposited conductor material (103) until those locations of the substrate which are not to have a conductive surface are free of a metal coating.

2. A method according to claim 1, characterised in that in step b there are produced recesses which have a cross section perpendicular to a surface of the substrate, in which cross section the aspect ratio, specifically the ratio between the depth (t) and the width (b) of the structures is at least 1:2 and for example at least 2:3 as well as at the most 5:1.

3. A method according to claim 2, characterised in that the aspect ratio is at least 1:1.

4. A method according to one of the preceding claims, characterised in that in step b there are produced structures which perpendicular to a surface of the substrate have a width of between 10 μm and 100 μm.

5. A method according to one of the preceding claims, characterised in that in step b there are also produced recesses where passage holes are to arise.

6. A method according to claim 5, characterised in that after the embossing step b and before the step c there is carried out an aftercleaning step.

7. A method according to one of the preceding claims, characterised in that in step b the substrate is simultaneously provided with recesses on both sides by two embossing dies (11, 13).

8 A method according to one of the preceding claims, characterised in that in the embossing step there are produced additional sections with a screened structure as a group of recesses separated from one another by projections, wherein the height of the projections (h′) is smaller than the depth (t) of the essentially channel-shaped recesses for the strip conductors.

9. A method according to one of the preceding claims, characterised in that the embossing step includes a coarse embossing step produced with a coarse embossing tool and following this, a fine embossing step produced with a fine embossing tool.

10. A method according to one of the preceding claims, characterised in that the electrolyte used in step d has 10-200 g/L of sulphuric acid, 50-500 g/L of copper sulphate and 10-250 mg/L of sodium chloride as well as organic additions.

11. A method according to claim 10, characterised in that the organic additions comprise 0.55 mL/L of HSO C-WL base gloss, 0.5-5 mL/L of HSO C-WL gloss substrate and 0.05-2 mL/L of HSO C-WL gloss addition.

12. A method according to claim 10 or 11, characterised in that the electrolyte comprises 20-100 g/L and preferably 45-70 g/L of sulphuric acid, 180-280 g/L and preferably 200-230 g/L of copper sulphate as well as 100-190 mg/L and preferably 140-170 mg/L of sodium chloride.

13. An electrical connecting element, manufactured with a method according to one of the preceding claims, characterised in that it comprises an insulating layer (101) consisting of a plastically deformable polymer with mechanically produced recesses, wherein at least some of the recesses have a cross section perpendicular to the surface of the insulating layer, in which cross section the aspect ratio is at least 1:2, and are essentially filled completely with galvanically deposited conductor material (103′) which may be applied as strip conductors.

14. An electrical connecting element according to claim 13, characterised in that the aspect ratio is roughly 1:1 or more.

15. An electrical connecting element according to claim 13 or 14, characterised by at least one region with a conductive contact surface which consists of a channel structure filled galvanically with conductor material, wherein the channel structure is designed as a row of recesses separated from one another by projections and wherein the projections are covered with the galvanically deposited conductor material.

16. An electrical connecting element according to one of the claims 13 to 15, characterised by passage holes produced in the embossing step b and in an aftercleaning step.

17. A semi-finished product for use as a component of an electrical connecting element, manufactured with the method according to one of the claims 1 to 12, characterised in that it comprises an insulating layer (101) consisting of a plastically deformable polymer with mechanically produced recesses, wherein at least some of the recesses have a cross section perpendicular to the surface of the insulating layer, in which cross section the aspect ratio is at least 1:2, and are essentially filled completely with galvanically desposited conductor material (103′) which may be applied as strip conductors.

18. An installation for manufacturing an electrical connecting element with the method according to one of the claims 1 to 12, containing a device (21) for producing recesses on plastically deformable substrates with at least one embossing die (9), a coating device (25) for the physical or chemical coating of an insulating substrate, an electroplating device (27) and a removing-away device (29), wherein the device (21) for producing recesses, the coating device (25), the electroplating device (27) and the removing-away device (29) are arranged such that they are passed through one after the other by a substrate to be processed whilst carrying out the method steps a to d.

19. An installation according to claim 18, characterised by an aftercleaning device (23), for removing dielectric material from a dielectric substrate, said aftercleaning device being arranged between the device (21) for producing recesses and the coating device (25).

20. An installation according to claim 18 or 19, wherein the device (21) for embossing a plastically deformable dielectric substrate comprises at least one embossing die (11, 13) with projections (11b, 11c) for producing recesses on the substrate, wherein there are present ridgelike projections (11b) with a cross sectional surface perpendicular to the middle surface of the embossing die, in which cross section the height (h′) of the ridge-like projections is at least half as large as their width (b′).

21. An installation according to claim 20, characterised in that the metioned ridge-like projections (11b) have an at least approximate rectangular cross section.

22. An installation according to claim 20 or 21, characterised in that the at least one embossing die additionally comprises pin-like projections (11c) for producing passage holes.

23. A device (21) for embossing a plastically deformable dielectric substrate, with at least two embossing dies (11, 13) with projections (11b, 11c) for producing recesses on the substrate, said embossing dies being designed and arranged for simultaneously producing recesses into both sides of a planar substrate, and wherein there are present ridge-like projections (11b) with a cross section surface perpendicular to the middle surface of the embossing die, in which cross section the height (h′) of the ridge-like projections is at least half as large as their width (b′), and the embossing dies additionally comprise pin-like projections (11c) for producing passage holes.
